(19) United States
(12) Patent Application Publication
(10) Pub. No.: US 2011/0127999 A1
(43) Pub. Date: Jun. 2, 2011

(54) PIPELINE INSPECTION APPARATUS AND METHOD

(76) Inventors: Paul Lott, Anchorage, AK (US); S.W. Billingsley, Brookeville, MD (US)

(21) Appl. No.: 12/856,424

(22) Filed: Aug. 13, 2010

Related U.S. Application Data
(60) Provisional application No. 61/234,233, filed on Aug. 14, 2009.

(51) Int. Cl. G01R 33/12

(52) U.S. Cl. 324/239

(57) ABSTRACT

Apparatuses and methods for inspecting a section of piping are disclosed. In one example embodiment, an apparatus includes first and second excitation coils, a plurality of magnetometers, and a data acquisition system. The first excitation coils are disposed at a first axial location and are energized and the second excitation coils are disposed at a second axial location and are energized at an opposite polarity from the first excitation coil. The plurality of magnetometers are disposed at an axial location between the first and second axial locations and are positioned to detect magnetic fields generated by eddy currents induced in the section of piping by the first and second excitation coils. The data acquisition system is operatively connected to receive output data from the plurality of magnetometers.

### CROSS-REFERENCE TO RELATED APPLICATIONS

This application is claims the benefit of provisional application No. 61/234,233, filed Aug. 14, 2009.

The entire disclosure of the prior application is considered to be part of the disclosure of the instant application and is hereby incorporated by reference therein.

### BACKGROUND

Inspection of various piping systems and pipelines for defects, cracks, corrosion, wear and the like is important for maintaining the integrity of such systems, and avoiding potentially catastrophic consequences from failure of pipes during use. In some applications the piping systems are used to transport hot and/or corrosive materials. Often such piping systems are provided with an exterior layer of insulation or the like, which prevents visual inspection of the piping system, and inhibits conventional inspection systems that require direct access to the pipes. In another example, piping systems for transporting petroleum products or the like over large distances often include a thick layer of polymeric insulation and an outer metal sheathing. Such piping systems are extremely difficult and costly to effectively monitor for wear, corrosion, damage and similar defects. Other piping systems are difficult to access for other reasons. For example, piping systems and risers associated with off-shore drilling, including for example steel catenary risers, are substantially located underwater, and therefore difficult and expensive to monitor. Such piping systems may also be coated or encased with a protective outer casing, for example a plastic or elastomeric outer jacket.

Conventional state of the art pipe inspection systems typically use insertable inspection probes, called inline inspection pigs that are inserted directly into the pipe and travel along the pipe. An inspection pig may be self-propelled, or may be carried through the pipe by the flow within the pipe.

Different technologies are used in inspection pigs. For example, U.S. Pat. No. 7,218,102 to Nestleroth et al. discloses an inspection pig having three magnets that are in magnetic contact with the interior of the pipe wall, and relies on magnetic flux leakage detection from the pipeline wall to identify defects such as metal loss. In another example, U.S. Pat. No. 6,651,503 to Bazarov et al. discloses an inspection pig that uses ultrasonic flaw detection. One obvious disadvantage of inspection pigs is that they require access to the interior of a pipe. For many pipe systems, accessing the pipe to insert the inspection pig can be problematic, as it typically requires shutting down the flow within the pipe, and some disassembly and/or use of an access port.

It would be advantageous to provide a pipe inspection apparatus that may be used for inspecting the condition of the pipe even when the pipe is not easily accessible and/or is covered with a protective covering.

### DESCRIPTION OF THE DRAWINGS

The foregoing aspects and many of the attendant advantages of this invention will become more readily appreciated as the same become better understood by reference to the following detailed description, when taken in conjunction with the accompanying drawings, wherein:

FIG. 1 is a diagram showing a pipe inspection apparatus in accordance with the present invention positioned for inspecting a section of insulated and sheathed pipe;

FIG. 2 is a perspective view of a first embodiment of the pipe inspection apparatus shown in FIG. 1, shown without the power supplies and data acquisition unit;

FIG. 3 is an end view of the pipe inspection apparatus shown in FIG. 2;

FIG. 4 is a diagram showing a second embodiment of a pipe inspection apparatus in accordance with the present invention, positioned for inspecting a section of sheathed piping;

FIG. 5 shows qualitatively the magnetic field induced by the first and second excitation coils of the apparatus shown in FIG. 4, as a function of axial distance along the section of piping;

FIG. 6 is a perspective view of a third embodiment of a pipe inspection apparatus in accordance with the present invention, shown on a section of insulated and sheathed pipe, and without the power supplies and data acquisition unit; and

FIG. 7 is an end view of the pipe inspection apparatus shown in FIG. 6.

### DETAILED DESCRIPTION

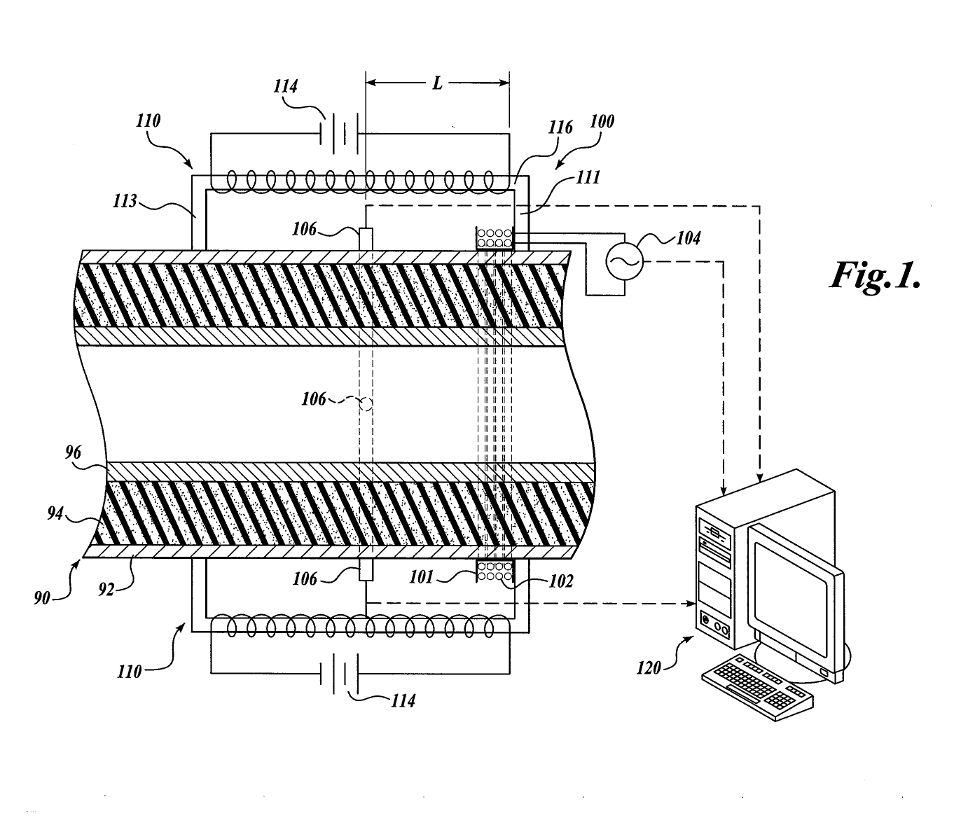

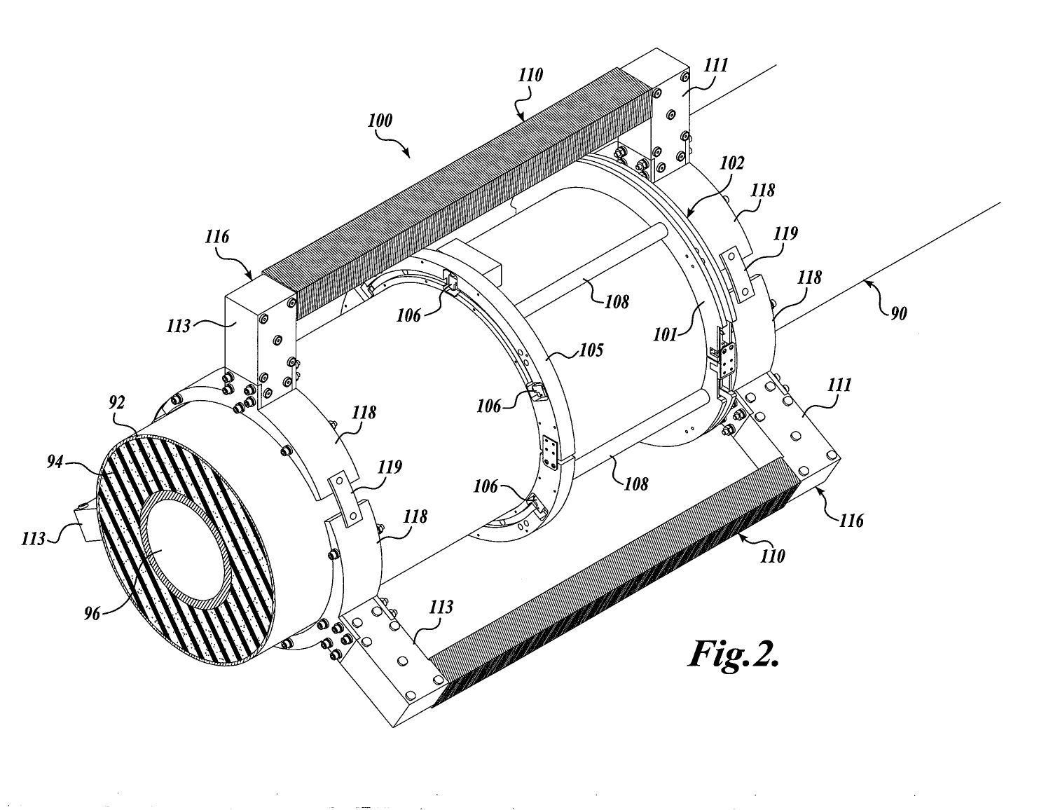

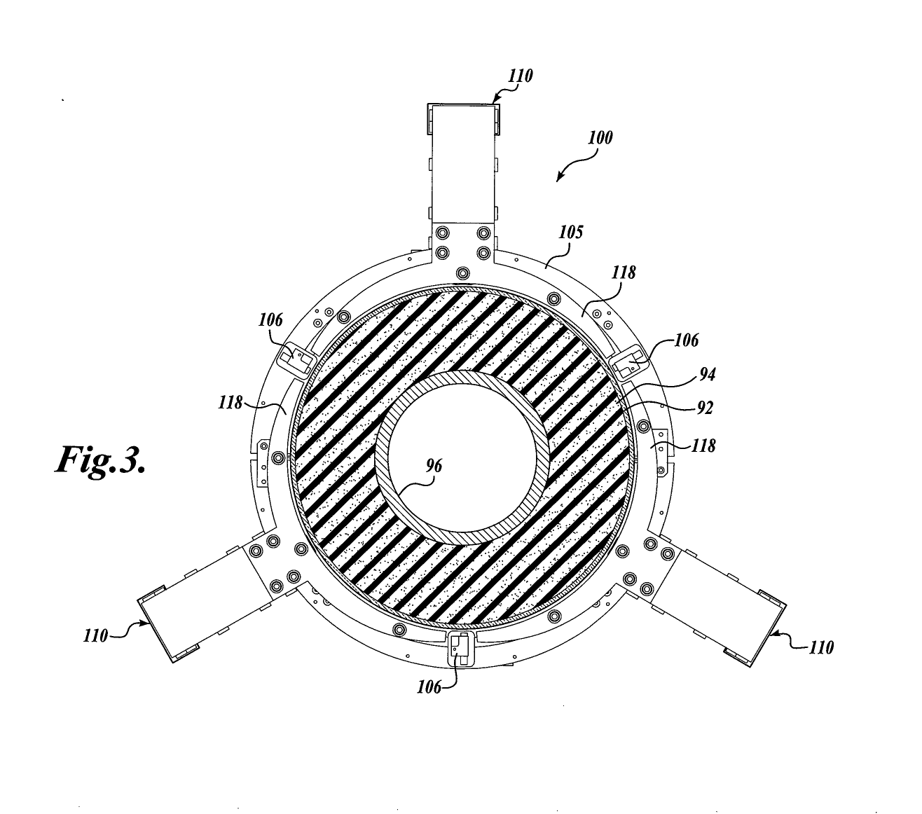

A first embodiment of an inspection system 100 in accordance with the present invention is shown schematically in FIG. 1. A perspective view of the pipe-mounted portions of the inspection system 100 is shown in FIG. 2, and an end view is shown in FIG. 3.

The inspection system 100 is particularly suitable for, but not limited to, inspecting a piping section 90 of the type having a magnetically permeable pipe 96 covered with a layer of insulation 94, and a magnetically permeable outer sheathing 92. In an exemplary above ground oil pipeline, for example, a steel pipe 96 approximately ½-inch in thickness is encased in an elastic polymeric insulation 94 that may be several inches thick. A galvanized steel sheathing 92 may be wrapped over the outer face of the insulation 94, and sealed to mitigate or prevent the intrusion of water into the pipeline. It will be appreciated by persons of skill in the art that a piping system such as this presents significant obstacles to nondestructive monitoring or inspecting of the condition of the pipe 96. For example, visual inspection is impossible without undertaking the arduous task of removing at least a portion of the sheathing 92 and insulation 94 from the pipe 96. The insulation 94 and the sheathing 92 also hinders placement of a probe in direct contact the pipe 96. The thickness of the insulation 94, in particular, prevents placing a probe in close proximity to the surface of the pipe 96. The sheathing 92 will typically interfere with conventional electromagnetic nondestructive examination (NDE) systems.

The inspection system 100 includes an excitation coil 102 that is positioned around the piping section 90 at a selected axial position. For convenience, the excitation coil 102 may be provided on a spool 101 having a hinge or other mechanism for opening the spool 101. For example, the coil 102 may be mounted on a hinged spool 101 wherein the individual loops of the coil 102 engage an electrical connector-type joint that is releasably engageable (not shown), such that the coil 102 may be opened for attachment to a piping section 90 from an intermediate location along the piping section 90.

An alternating current source 104 is operatively connected to the excitation coil 102, to selectively energize the coil 102. In this embodiment, the coil 102 is energized at a low frequency, for example less than 100 Hz, and for some applications less than 10 Hz. An excitation frequency of less than 5 Hz will be suitable for many pipeline applications. However, it will be appreciated that optimal frequency range will depend on the particular geometry of the piping to be examined. It is believed to be well within the skill in the art to identify a suitable frequency for a given piping section configuration.

A plurality of magnetic field detectors, for example magnetometers 106 are positioned about the piping section 90 at an axial distance L from the excitation coil 102. In a current embodiment the magnetometers 106 comprise vector magnetometers, and more particularly fluxgate magnetometers. A suitable power supply (not shown) for the magnetometers 106 is also provided. It is contemplated that other types of magnetic field detectors may alternatively be used, for example magnetoresistive magnetometers (e.g., giant magnetoresistive or anisotropic magnetoresistive magnetometers).

The magnetometers 106 are circumferentially spaced around the piping section 90 approximately adjacent the sheathing 92. For convenience the magnetometers 106 are mounted on an annular frame 105 for easy and consistent positioning. The frame 105 may also be hinged or otherwise openable, such that the magnetometers 106 may engage the piping section 90 from an intermediate location. In a current embodiment six fluxgate magnetometers 106 are positioned at equal circumferential intervals about the piping section 90. In another embodiment twelve magnetometers are mounted to the frame. In general, it is believed that more magnetometers 106 will provide greater resolution of the condition of the pipe 96. More magnetometers 106 may be desired to examine, for example, larger diameter piping. As seen most clearly in FIG. 2, the spool 101 and magnetometer frame 105 may be interconnected with spacers 108, such as longitudinal rods or the like, to maintain a desired spacing between the coil 102 and the magnetometers 106.

A yoke assembly comprising a plurality of electromagnets 110 (three shown in FIG. 3) are mounted about the piping section 90, and positioned such that a first pole 111 of each of the electromagnets 110 is disposed adjacent the coil 102, and the opposite pole 113 is positioned on the other side of the magnetometers 106 such that the magnetometers 106 are positioned approximately at the midpoint between the poles 111, 113 of the electromagnets 110. The ferromagnetic core 116 of each of the electromagnets 110 is formed with leg portions that extend from either end of the core 116 and engage curved supports 118 that are shaped to abut the outer sheathing 92 of the piping section 90. Releasable connectors 119 interconnect the curved supports 118, and hold them securely to the piping section 90.

Referring again to FIG. 1, one or more DC power supplies 114 provide power to energize the electromagnets 110. It will now be appreciated that the electromagnets 110 produce a magnetic field that at least partially saturates the magnetically permeable outer sheathing 92, thereby improving the ability of the excitation coil 102 to induce eddy currents in the pipe 96. The magnetometers 106 are preferably located midway between the poles 111, 113 to minimize or eliminate interference from the magnetic field produced by the electromagnets 110, optimizing the ability of the magnetometers 106 to detect the magnetic fields induced by the eddy currents in the pipe 96. Although electromagnets 110 are shown and currently preferred, it is contemplated that other magnetic means, for example rare earth magnets or the like, may alternatively be used. Alternatively, as indicated by the second embodiment below, the inspection may be conducted without the electromagnets 110. For example, in piping configurations wherein no magnetically permeable sheathing 92 is present, the system without electromagnets may be preferred. Even in applications wherein a sheathing 92 is present the electromagnets 110 may not be used so long as magnetic fields generated from eddy currents induced in the pipe 96 by the coil 102 can be adequately detected. Generally, embodiments of the invention may be used for inspecting pipes of different configurations, for example, pipes not having insulation disposed between a sheathing and the pipe, or not having a sheathing covering the pipe. Embodiments of the invention may be used for inspecting pipes having different sheathing materials. For example, pipes having non-metallic sheathing or coating, such as those having concrete coatings or having high-density polyethylene coatings, may be inspected using embodiments of the invention.

A data acquisition system 120 is operatively connected to the magnetometers 106 and the AC power supply 104. The data acquisition system 120 controls or monitors the application of the AC power to the excitation coil 102, and receives the sensor date from the magnetometers 106, which data is used to evaluate and inspect the pipe 96 in the vicinity of the magnetometers 106. The data acquisition system 120 may be physically connected to the system 100 or wireless means may be used to communicate with the other components of the system, as is well-known in the industry.

It should also be appreciated that although a separate data acquisition system 120 and AC power supply 104 are indicated in FIG. 1, it is contemplated and will be within the skill in the art to alternatively provide an on-board microcomputer board or the like and a suitable power supply to control the operation and record data received from the magnetometers 106, providing a stand-alone pipe-mounted systems.

It is also contemplated that automated operation of the system may be readily accomplished by providing components for sensing the position and/or movement of the system 100. For example, in a current embodiment the system is provided with a global positioning system (GPS) module, and with triaxial accelerometers. Data from the GPS, accelerometers and magnetometers may be wirelessly transmitted to an on-board or remote data acquisition system.

To inspect a piping section 90 the excitation coil 102 and magnetometers 106 are placed about the piping section 90. The yoke assembly electromagnets 110 are positioned such that the first poles 111 are disposed approximately adjacent the excitation coil 102, with the magnetometers 106 located approximately midway between the first poles 111 and opposite poles 113. The electromagnets 110 are powered to produce the desired magnetic field, and a low frequency current is applied to the excitation coil 102. The responsive signals from the magnetometers 106 are received by the data acquisition unit 120. The entire assembly is then moved axially along the piping section 90, and the magnetometer 106 data sequentially recorded. The data is then analyzed to identify and evaluate locations of defects in the pipe 96.

It will be appreciated by persons of skill in the art that the eddy currents produced in the pipe 96 by the excitation coil 102 will be impacted by defects or other anomalies in the pipe such as cracks, corrosion, pitting or the like. Changes in the eddy currents produced in the pipe 96 will cause corresponding changes in the magnetic fields induced by the eddy currents. Therefore, the data received from the magnetometers 106 may be used to identify defects and/or regions of concern in the pipe 96. It is contemplated that the process of moving the pipe inspection system 100 axially along the piping section 90 may be automated.

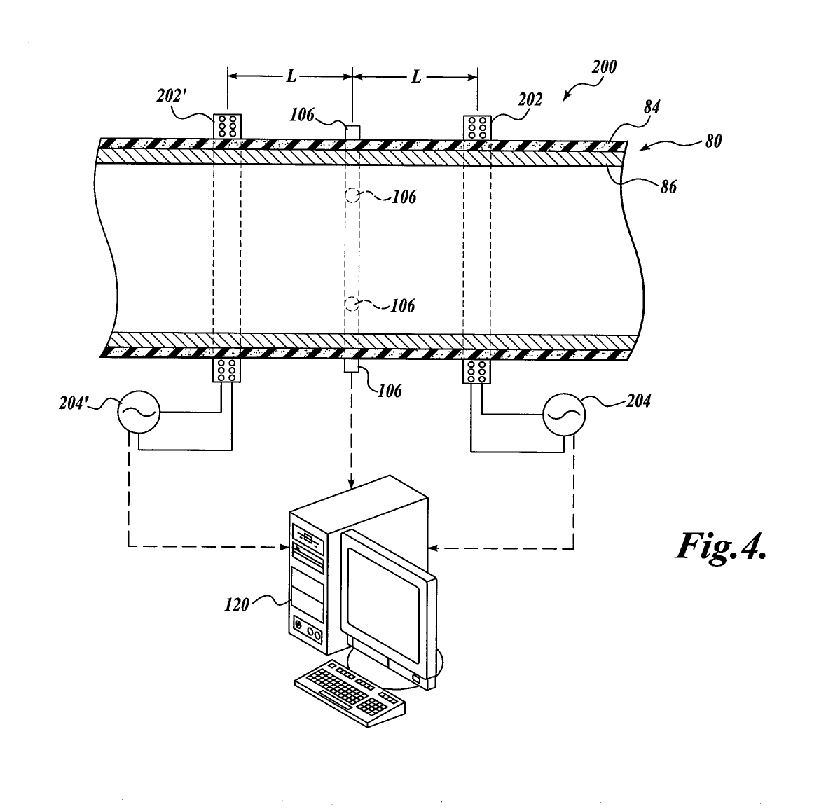

A second embodiment of a pipe inspection system 200 in accordance with the present invention is shown schematically in FIG. 4, disposed on a piping section 80 comprising a pipe 86 that is encased or covered with a sheath or protective covering 84, which may be formed for example from a polymeric material. The piping section 80 may be, for example, an undersea pipe or pipe riser, for example a steel catenary riser or the like. In this embodiment the inspection system 200 includes two spaced-apart excitation coils 202, 202′. The excitation coils 202, 202′ may be substantially similar to the excitation coil 102 described above, and may be mounted on spools 101 or the like. The magnetometers 106 are circumferentially spaced around the piping section 86, and are located midway between the excitation coils 202 and 202′, such that the magnetometers 106 are a distance L from each excitation coil 202, 202′.

The first excitation coil 202 is connected to an AC power supply 204 that produces a first alternating current, and the second excitation coil 202′ is connected to the AC power supply 204′ such that the second excitation coil is energized with a second alternating current that is of opposite polarity but otherwise the same as the first alternating current. The AC power supply 204′ may be a separate power supply from AC power supply 204, but preferably is the same power supply, simply wired series opposing such that an opposite polarity signal is applied to the second excitation coil 202′.

Excitation currents ranging from 2 amps to 20 amps have been used and found to be effective, with the eddy current signal strength increasing with increasing excitation current. Use of excitation currents greater than 20 amps is also contemplated. In an exemplary embodiment an excitation current pulse is applied for approximately 1.5 seconds at each testing point, so the total power requirements even at higher amperages are not prohibitive.

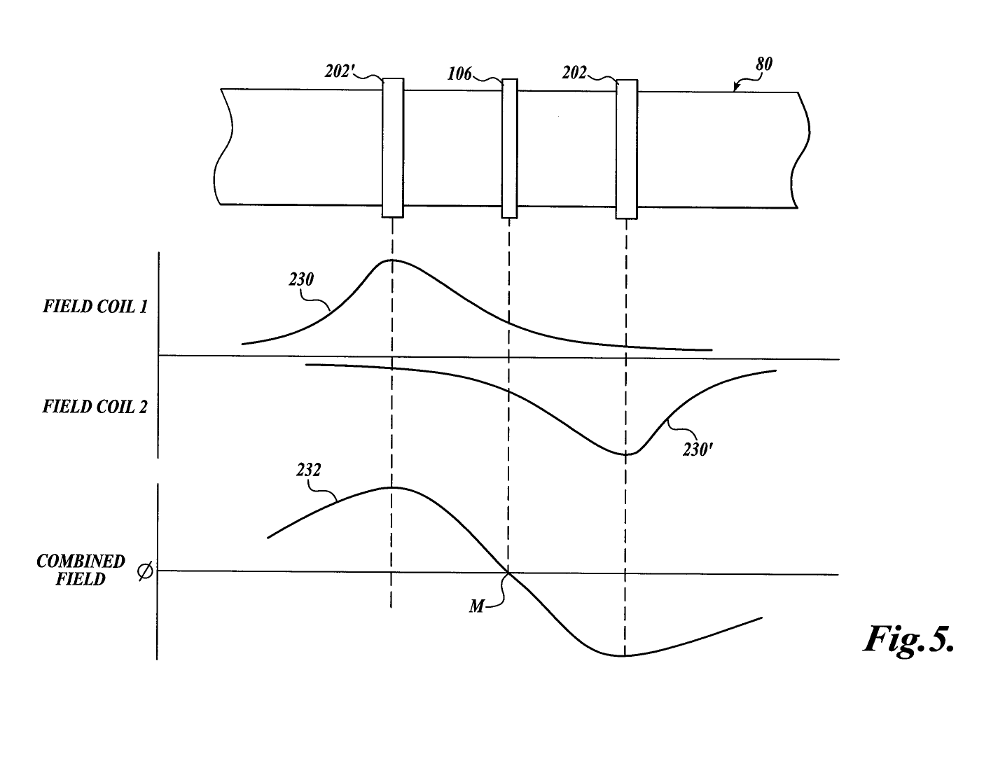

FIG. 5 shows schematically and qualitatively the magnetic field 230 induced by the first excitation coil 202, and the magnetic field 230′ induced by the second excitation coil 202′ as a function of axial distance along the piping section 80, when the coils are driven by equal but reverse polarity currents. FIG. 5 also shows the combined magnetic field 232. It will be appreciated that although the combined magnetic field varies over the piping section 80, the combined field is approximately zero at the location M of the magnetometers 106. It will be appreciated by persons of skill in the art, based on the disclosure herein, that the zeroing of the magnetic field at the location M of the magnetometers 106 improves the sensitivity of the magnetometers 106 to the magnetic fields induced by eddy currents in the pipe 86.

Although the second embodiment inspection system 200 is illustrated on a piping section without a magnetically permeable outer sheathing, the system 200 has also been used on piping sections 90 such as that shown in FIG. 1, and produces good results. The second embodiment 200 is also believed to be suitable for applications where access may be difficult, such as subsea piping and riser systems because no yoke assembly is required.

It will be appreciated that the coils 202, 202′, magnetometers 106 and associated components may be conveniently housed, for example in a clamshell-style composite housing (not shown). The assembly is moved along the piping section 80, and the coils 202, 202′ are periodically energized. The eddy current signal recorded by the magnetometers 106 are recorded to a data acquisition unit. As discussed above, optional motion tracking systems, such as accelerometers and/or GPS systems may be provided to detect and track the motion of the system 200 along the piping section 80. It is contemplated that the system 200 may be provided with a drive system (not shown) for automatically moving the system 200 along the piping section 80, or may be configured for manual operation.

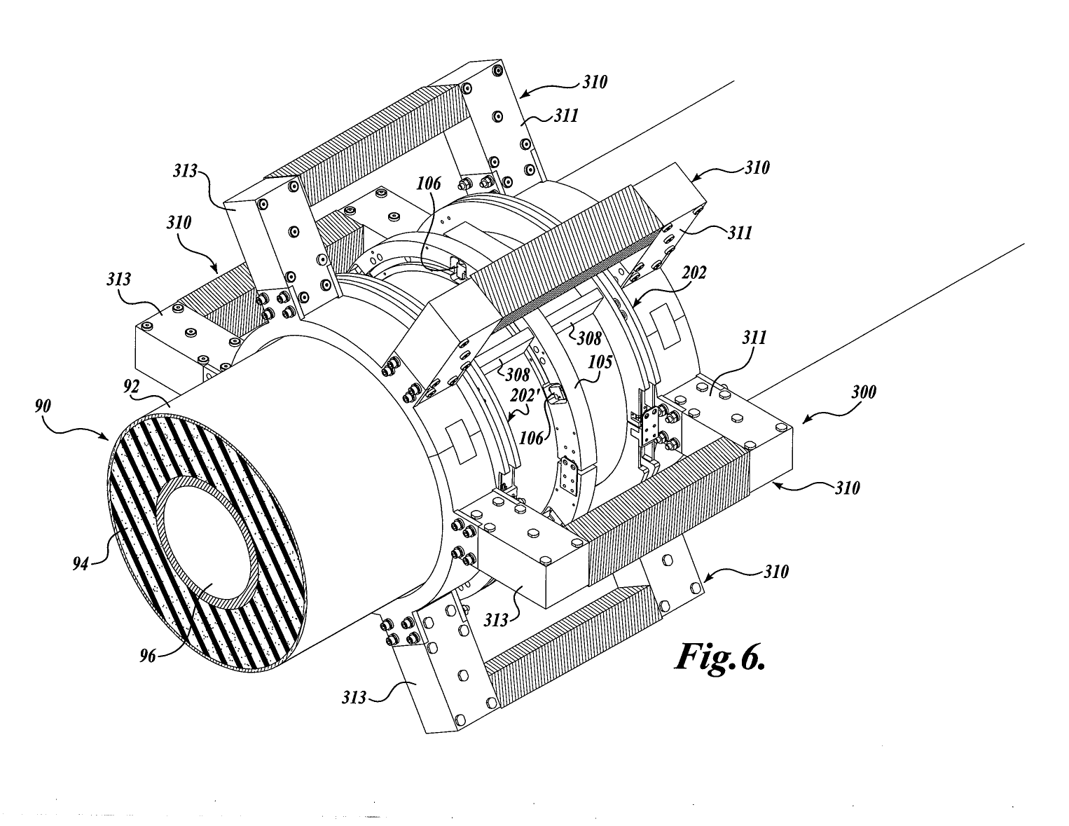

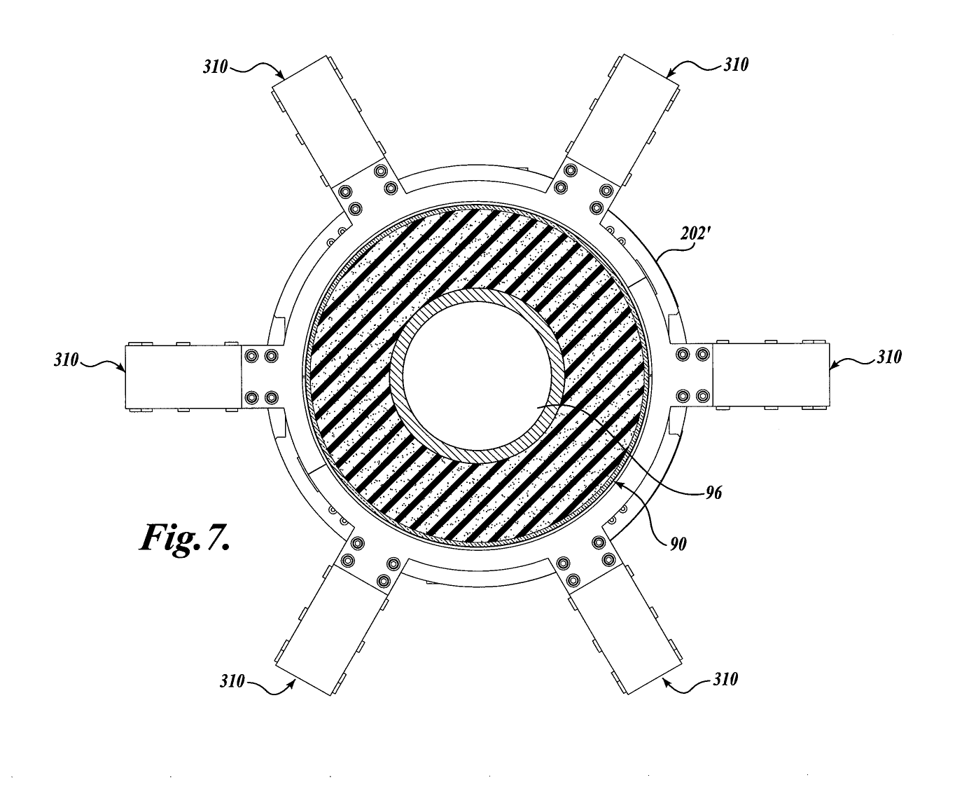

A third embodiment of a pipe inspection system 300 in accordance with the present invention is disclosed in FIGS. 6 and 7 (without the power supplies, or data acquisition unit). This embodiment generally combines the first and second embodiments disclosed above. The third system 300 uses two excitation coils 202, 202′ similar to the second embodiment 200 described above. The excitation coils 202, 202′ are preferably energized with similar, but opposite polarity alternating currents, as discussed above.

A yoke assembly similar to the first embodiment 100 described above is also provided. In this embodiment, the yoke assembly comprises six electromagnets 310, equally spaced about the piping section 90. The first excitation coil 202 is disposed adjacent a first pole 311 of the electromagnets 310, and the second excitation coil 202′ is disposed adjacent the opposite pole 313. It will be appreciated that the use of electromagnets 310 (in this case six rather than three) permits a strong saturating magnetic field to be induced in the sheathing 92 with a shorter overall system length. Although electromagnets are disclosed, it is contemplated that other magnetic means, such as permanent magnets, may alternatively be used.

The magnetometers 106 are located midway between the two excitation coils 202, 202′ and therefore also midway between the first pole 311 and opposite pole 313 of the electromagnets 310. The magnetometers 106 are therefore at a centered position with respect to the magnetic field induced by the electromagnets 310, and at a centered position with respect to the two excitation coils 202, 202′.

The previously described embodiments are described as having the magnetometers arranged around the circumference of the surface in a frame. In alternative embodiments, the magnetometers are arranged around the circumference of the surface in a plurality of frames. The plurality of frames may be disposed between the excitation coils. The frames may be positioned between the coils adjacent one another. The frames may also be evenly spaced between the coils in some embodiments. In some embodiments, the magnetometers of one frame may be angularly offset from the magnetometers of another frame.

The previously described embodiments of the invention have been shown and described as extending around the entire circumference of the pipe to be inspected. However, in alternative embodiments of the invention, the coils and magnetometers can extend over a portion less than the entire circumference. For example, although the particular embodiment illustrated in and described with reference to FIGS. 4 and 5 includes coils 202, 202′ and magnetometers 106 that extend around the entire circumference of the pipe to be inspected, the coils and magnetometer may extend over a shorter arc along the surface to be inspected. For example, in some embodiments, the coils 202, 202′ and the magnetometers 106 extend over half of the circumference of the pipe to be inspected. In other embodiments, the coils 202, 202′ may extend over a greater or lesser portion of the surface than one-half of the circumference.

Moreover, arrangement of the coils and magnetometers are not limited to an arrangement along a concave arc to be positioned against the exterior of a curved surface. For example, the coils and the magnetometer may be arranged in a substantially planar arrangement. Such an embodiment may be advantageous for inspecting a substantially planar surface, of a curved surface having a relatively large diameter of curvature. The coils and the magnetometer may also be arranged along a convex arc to be positioned against the interior of a curved surface. Such an embodiment may be advantageous for inspecting an interior curvature of a curved surface.

While a preferred embodiment of the invention been illustrated and described, it will be appreciated that various changes can be made therein without departing from the spirit and scope of the invention.

1. An apparatus for inspecting a section of piping, the apparatus comprising:
an alternating current power source;
a first excitation coil disposed at a first axial location, the first excitation coil being energized by the alternating current power source;
a second excitation coil disposed at a second axial location, the second excitation coil being energized at an opposite polarity from the first excitation coil;
a plurality of magnetometers disposed at an axial location between the first axial location and the second axial location, wherein the magnetometers are positioned to detect magnetic fields generated by eddy currents induced in the section of piping by the first and second excitation coils; and
a data acquisition system operatively connected to receive output data from the plurality of magnetometers;
wherein the apparatus is movable axially along the section of piping.

2. The apparatus of claim 1 wherein the first excitation coil is disposed around the section of piping at the first axial location.

3. The apparatus of claim 1 wherein the plurality of magnetometers are circumferentially spaced around the second of piping at the axial location between the first and second axial locations.

4. The apparatus for inspecting a section of piping of claim 1, wherein the magnetometers comprise fluxgate magnetometers.

5. The apparatus for inspecting a section of piping of claim 1, wherein the magnetometers are located half way between the first excitation coil and the second excitation coil.

6. The apparatus for inspecting a section of piping of claim 1 wherein the magnetometers are disposed in a ring around the section of piping at the first axial location.

7. The apparatus for inspecting a section of piping of claim 1, further comprising a first openable bobbin that supports the first excitation coil and a second openable bobbin that supports the second excitation coil.

8. The apparatus for inspecting a section of piping of claim 7, further comprising an openable frame that supports the plurality of magnetometers.

9. The apparatus for inspecting a section of piping of claim 7, wherein the frame and the first and second bobbins opens and close about a longitudinal axis such that the apparatus can be opened for positioning around the section of piping and closed for performing the inspection.

10. The apparatus for inspecting a section of piping of claim 1, wherein the data acquisition system receives output data from the plurality of magnetometers wirelessly.

11. The apparatus for inspecting a section of piping of claim 1, further comprising means for detecting movement of the apparatus along the section of piping.

12. The apparatus for inspecting a section of piping of claim 1, wherein the first and second excitation coils are energized with a current in the range of 5-20 amps, with a pulse interval of less than two seconds.

13-21. (canceled)

22. A method for examining a section of piping having a magnetically permeable pipe, the method comprising the steps:
placing a first excitation coil proximate said section of piping at a first axial location;
placing a plurality of magnetometers proximate said section of piping at a first distance from said first axial location, wherein said magnetometers are oriented toward said magnetically permeable pipe;
energizing said first excitation coil with an alternating current;
monitoring said plurality of magnetometers and recording a plurality of signals therefrom to a data acquisition unit; and
inferring from said plurality of signals a physical condition of said magnetically permeable pipe.

23. The method of claim 22, further comprising placing a second excitation coil proximate said section of piping opposite the plurality of magnetometers from the first excitation coil, and energizing said second excitation coil simultaneously with energizing said first excitation coil and with an alternating current opposite in polarity from the first excitation coil alternating current.

24. (canceled)

25. The method of claim 22, wherein said magnetometers are fluxgate magnetometers.

26. The method of claim 22, further comprising the step of moving said excitation coil, said plurality of magnetometers and said electromagnets along said section of piping to a second position, and monitoring said plurality of magnetometers to receive a second plurality of signals therefrom.

27. The method of claim 22, wherein said alternating current is less than 10 Hertz.

28. (canceled)
